(19) United States
(12) Patent Application Publication
(10) Pub. No.: US 2025/0237491 A1
(43) Pub. Date: Jul. 24, 2025

(54) SELF-MIXING INTERFEROMETRY SENSOR MODULE, ELECTRONIC DEVICE AND METHOD OF DETECTING MOVEMENTS

(71) Applicant: ams International AG, Jona (CH)

(72) Inventors: Markus DANTLER, Thalwil (CH); Remi FRANCARD, Strasbourg (FR); Liviu DANAILA, San Jose, CA (US); Laurent NEVOU, Wadenswil (CH)

(21) Appl. No.: 18/838,462

(22) PCT Filed: Feb. 14, 2023
(86) PCT No.: PCT/EP2023/053619

§ 371 Date: Aug. 14, 2024

Related U.S. Application Data
(60) Provisional application No. 63/310,233, filed on Feb. 15, 2022.

(51) Int. Cl. G01B 9/02; G01P 3/36; G06F 3/01; G06F 3/03; G06F 3/0354; G06F 3/038; H01S 5/183

(52) U.S. Cl. CPC G01B 9/02092; G01P 3/36; G06F 3/017; G06F 3/0304; G06F 3/03547; G06F 3/038; H01S 5/183

(57) ABSTRACT

A self-mixing interferometry sensor module includes a light emitter and an electronic control unit coupled to the light emitter. The light emitter is configured to emit coherent electromagnetic radiation out of the sensor module. The light emitter is also configured to undergo self-mixing interference (SMI) caused by reflections of the emitted electromagnetic radiation from an object outside the sensor module. The electronic control unit is configured to detect a change in an electrical property of the light emitter caused by the SMI. The electronic control unit is also configured to determine from the detected change a movement of the object outside the sensor module. The electronic control unit is further configured to generate an output signal that includes information of the determined movement.

The present invention relates to a self-mixing interferometry sensor module, an electronic device and to a method of detecting movements.

### BACKGROUND OF THE INVENTION

Modern consumer electronics devices, such as mobile phones, radios, tablet computers, wearables and TV remote controls contain mechanical means, e.g. buttons, or other interfaces that allow the user to control various functions such as volume control and channel selection. Besides that, state-of-the-art in-ear-loudspeaker devices feature sensors that are configured to detect a tapping with a user's finger on the housing of the device. This signal is in turn used for some, however limited, controls e.g. to stop or resume the playback of music, or to skip to the next or previous song in a playlist. However, to date there is no possibility for a user to adjust, i.e. increase or decrease, the volume of the sound output or to specifically fast forward to a different part of the audio media, e.g. an audio book, currently being played, for instance.

Moreover, the integration of mechanical control buttons in an electronic device and in the housing for the device can be complicated and harbors additional quality risks, especially in the case of very small devices. Specifically, mechanical buttons typically require a lot of space, which is often scarce in compact devices such as smartphones or wearables.

In addition, openings in the housing provided and required for the mechanical buttons pose a risk of dust and water penetration, potentially causing permanent damage to the device. Such problems are conventionally solved by additional sealing or protective parts, however, these features further add complexity and cost of the device. Furthermore, the life time of mechanical pushbutton systems is known to be limited, e.g. due to mechanical springs that are connected to the push buttons and tend to wear out over time.

Existing approaches for overcoming these limitations include optoelectronic modules that are operable to respond to a user's finger movement for controlling the device. These approaches have the disadvantage that such modules require a plurality of components, e.g. at least one light emitter and preferably two or more light receiving elements like photodiodes for detecting light reflected of the user's finger. As a result, these modules are rather bulky and even larger than mechanical pushbutton modules.

Thus, an object to be achieved is to provide a sensor module for electronic devices that overcomes the aforementioned limitations of existing solutions. A further object is to provide an electronic device comprising such a sensor module and a method of detecting movements.

These objects are achieved with the subject-matter of the independent claims. Further developments and embodiments are described in dependent claims.

### SUMMARY OF THE INVENTION

The improved concept is based on the idea of providing a self-mixing interferometry sensor module operable to respond to various user's finger and/or gesture movements for controlling an electronic device. Therein, the movement sensing is based on the occurrence of self-mixing, or back-injection, interference, in which at least a part of the emitted light is reflected off a target outside the module, e.g. a user's finger, back into a cavity of the light emitter causing a modulation in frequency of the emitted optical beam, which in turn also modulates an electronic property of the emitter. In other words, the light emitter itself effectively becomes a distance and/or speed sensor as a degree of the resultant modulation depends on these properties of the moving object. The advantage compared to traditional sensor modules is a significantly decreased footprint of the sensor and a lower cost owing to the absence of complicated collimation optics and photodiodes in case of a voltage readout only, for instance.

In an embodiment, a self-mixing interferometry sensor module according to the improved concept comprises a light emitter that is configured to emit coherent electromagnetic radiation out of the sensor module, and to undergo self-mixing interference, SMI, that is caused by reflections of the emitted electromagnetic radiation from an object outside the sensor module. The self-mixing interferometry sensor module further comprises an electronic control unit that is coupled to the light emitter and configured to detect a change in an electrical property of the light emitter caused by the SMI. The electronic control unit is further configured to determine from the detected change a movement of the object outside the sensor module, and to generate an output signal that comprises information of the determined movement.

The light emitter for enabling self-mixing interference, comprises a cavity resonator, into which at least a fraction of the light emitted by the light emitter is reflected, or backscattered, from an object outside the module. For example, the light emitter is a laser diode and comprises a laser cavity. The light emitter is configured to emit coherent light, e.g. in an infrared (IR), visible or ultraviolet (UV) portion of the electromagnetic spectrum, out of the sensor module. For example, the light emitter is configured to generate a continuous emission or to emit light in a pulsed mode, the latter potentially aiding in an overall reduction of power consumption.

Upon the aforementioned back-injection of the emitted light into the cavity and due to a movement of the object outside the module the light is reflected off, the light emitter is configured to undergo self-mixing interference, SMI. The SMI alters a property, e.g. a wavelength, of the light within or emitted from the laser cavity, e.g. it causes a modulation in a frequency of the emitted light, hence generating a periodic fringing signal. The modulation in turn causes a change of an electronic property of the light emitter. For example, a diode current and/or voltage is likewise modulated. When no target is present outside the module in the field of emission of the light source so as to intercept and reflect light of the latter, no self-mixing interference occurs within the light emitter.

The electronic control unit comprises means, e.g. active or passive circuitry, to measure said change in an electronic property. Since the change in the electronic property depends on the movement of the object, the electronic control unit comprises further circuitry for deriving from the change in the electronic property a movement of the object, e.g. in terms of a change of position, direction and/or speed. Based on the determined movement, the electronic control unit further comprises means to generate an output signal that contains information of the determined movement. For example, the movement is a movement perpendicular or parallel to an emission direction of the light emitter. The output signal comprises information about the movement, e.g. it comprises information of speed, duration and/or direction of the movement as well as a distance of the object, e.g. measured in an emission direction of the light emitter.

For example, the light emitter and the electronic control unit form an integrated semiconductor device, such as a CMOS integrated circuit device, on a common substrate. In particular, a sensor module according to the improved concept is free of any dedicated photodetectors for sensing reflected or backscattered light.

An electronic device may use such a self-mixing interferometry sensor module as part of detecting a displacement, distance, motion, speed, or velocity of an object outside the module, e.g. a gesture at a distance from the sensor module or a movement with respect to an input surface of the module, i.e. a so-called swiping or tapping movement. Hereinafter, all such possibly measured parameters will be referred to simply as “movement.” Specifically, such a self-mixing interferometry sensor module can be used with a wide range of consumer and other electronic devices and can serve as an input module replacing mechanical buttons and comprising additional degrees of freedom, hence facilitating a user's control of features such as volume, as well as song, channel or page selection, depending on the application.

In some embodiments, the light emitter is a vertical cavity surface emitting laser, VCSEL, diode. VCSEL diodes are characterized by a beam emission that is perpendicular to a main extension plane of a top surface of the VCSEL. The VCSEL diode can be formed from semiconductor layers on a substrate, wherein the semiconductor layers comprise two distributed Bragg reflectors (DBR) enclosing active region layers in between and thus forming a cavity. VCSELs and their principle of operation are a well-known concept and are not further detailed throughout this disclosure. For example, the VCSEL diode is configured to have an emission wavelength of 940 nm, 850 nm, or another natural wavelength. The VCSEL diode can be configured to emit coherent laser light when forward biased, for instance. Suitable alternative light emitters include semiconductor lasers such as edge emitters, quantum cascade and quantum dots laser.

In some embodiments, the electronic control unit is configured to detect a change in a junction voltage of the light emitter and determine from the change in junction voltage the movement of the object. A quantity other than a wavelength (and an optical power since it is related to the emission frequency) that is affected by self-mixing is typically a laser junction voltage. Therein, it is noted that both the output frequency and the junction voltage in consequence show a dependency with the movement.

Hence, a measurement of the junction voltage, e.g. the junction voltage of a VCSEL, provides a convenient way to determine a movement of the object, e.g. a finger, as its signature is directly and essentially without delay transferred to the junction voltage of the light emitter, e.g. of the VCSEL diode. Alternatively, a modulation of the bias current could be detected as the changing electronic property of the light emitter, for instance.

In some embodiments, the electronic control unit is configured to detect a frequency modulation of the electrical property caused by the SMI, and determine from the detected frequency modulation the movement of the object. Detecting a frequency modulation provides not only means to detect a movement of the object, but can also give further-reaching details about said movements. An amplitude of the resultant modulation signal can indicate a position of the object within the emission area, e.g. a light cone or beam, of the light emitter, while a comparison of rising and falling slopes of the modulation signal can indicate a direction of movement, for instance. Moreover, if the object is a user's finger, due to the unique pattern of each finger's friction ridges forming the human fingerprint, the modulation signal can even give information about what finger of the user is moved across or within the emission area of the light emitter. However, it is noted that also an apparently smooth object, such as a slider still provides sufficient topography for allowing interferometric displacement measurements using SMI.

In some embodiments, the electronic control unit is further configured to determine, from the detected change, a speed of the movement, and to generate the output signal that comprises information of the determined speed. As optical interferometry provides extremely sensitive means for detecting displacement, the modulation signal caused by SMI due to a slowly moving object substantially differs from that of a faster moving object. Particularly for human fingers, the pattern formed by the friction ridges is sufficient to even resolve a difference in a speed of the movement of the object. Hence, the change in the electronic property of the light emitter in such embodiments carries information about a speed of the movement of the object. Said information can be included in the generation of the output signal, such that it can be used for adjusting a feature of an electronic device dependent on the detected speed. For example, a playback speed or the speed of a fast forwarding/rewinding could be adjusted in dependence of the detected speed.

In some embodiments, the electronic control unit is further configured to determine from the detected change a direction of the movement along a movement axis, and generate the output signal that comprises information of the determined direction. In addition or alternatively to the aforementioned detection of speed, optical interferometry is predestinated for displacement measurement. Thus, analogous to the aforementioned determination of a movement speed, a modulation due to SMI can also carry information about a direction of movement. For example, the resultant change of the signal of the electronic property of the light emitter can be analyzed in terms of the rising and falling slopes of an amplitude modulation. For example, a rising slope that is steeper than the falling slope can indicate a movement forward along a given axis, e.g. an x-axis, that is perpendicular to an emission direction of the light emitter, while a steeper falling slope in the signal can indicate a movement backward along the first axis. Moreover, the resultant modulation signal of the electronic property can carry information of a movement backward or forward along a second axis that is perpendicular to both the first axis and an emission direction, as well as along a third axis that is perpendicular to the first and second axes and parallel to an emission direction, e.g. a tapping.

In some embodiments, the electronic control unit is further configured to determine from the detected change an orientation of the movement with respect to a first axis and a second axis, and generate the output signal that comprises information of the determined orientation. In addition or alternatively to the aforementioned detection whether the movement occurs in a first or second direction along a specific axis, the resultant signal due to the SMI is likewise distinguishable in terms of whether the movement is oriented along a first axis, e.g. an x-axis, or along a second axis, e.g. a y-axis, wherein the first and second axes are perpendicular to each other and to an emission direction of the light emitter, for instance. Likewise, the electronic control unit can be further configured to determine from the detected change an orientation of the movement with respect to a third axis that is parallel to an emission direction of the light emitter, e.g. a z-axis. Furthermore, the electronic control unit can be configured to determine a deviation of an orientation of the movement with respect to the first and second axes. In particular, a single light emitter is sufficient to determine a direction and an orientation of the movement along all three motion principle axes of the object.

In some embodiments, the electronic control unit is configured to determine from the detected change a movement of a finger of a user outside the sensor module. In other words, the object is a finger. As described above, the friction fringes of a human finger pose an excellent target of reflection for causing self-mixed interference. As optical interference is able to resolve displacements in the order of fractions of the optical wavelength of light, the several tens of micrometer thick fringes of fingers are more than sufficient to cause an interference signal with a large enough signal-to-noise ratio for accurately determining aspects of the movement such as a direction of movement or a speed. As fingers are the most common means for input in modern electronic devices, a SMI sensor module that is configured to detect a movement of fingers outside the sensor module provides an efficient and extremely accurate way of detecting user inputs. Compared to existing capacitive technologies, e.g. used in touch screens, the detection via SMI due to the extreme sensitivity provides additional capabilities such as gesture recognition or finger-dependent generation of an output signal.

In some embodiments, the electronic control unit is further configured to identify from the detected change a finger of the user, and generate the output signal that comprises information of the identified finger. In addition to determining aspects of the movement itself, the modulation signal due to self-mixing interference from the finger fringes is strong enough to also discern individual fingers of a user. For example, the output signal can comprise information about what finger of a user, i.e. thumb, index finger, ring finger etc., of which hand is moved through or within the field of emission of the light emitter. Said information can be included in the generation of the output signal and can be used for adjusting a feature of an electronic device dependent on the identified finger. For example, using an index finger a sound volume can be adjusted, while a movement performed with a middle finger into the same direction/orientation could skip to a next or previous item of a playlist. Moreover, sequences of movements can be used for security purposes, e.g. for unlocking or locking an electronic device. Therein, a specific movement or movement sequence can be used to lock a wearable or smartphone device for avoiding unintended touch inputs, e.g. when stored in a pocket or during an exercise. A further specific movement or movement sequence can be used to unlock the device and enable touch inputs. To this end, the output signal can comprise information about a movement of a first finger, e.g. a movement of an index finger in a first direction along a first orientation, and a second finger, e.g. a movement of a middle finger in a second direction along a second orientation, and so on. To this end, the electronic device can comprise a memory that contains information about the user's fingers that have been acquired during an initial training procedure, for instance.

In some embodiments, the self-mixing interferometry sensor module further comprises a transmissive cover that is arranged distant from the light emitter in an emission direction of the light emitter, wherein the transmissive cover serves as a surface for the movement of the object. In general, a moving object to be detected, e.g. a user's finger, preferably should remain at approximately the same height above the sensor module, i.e. the light emitter, as the user moves the finger through or within the emission area of the light emitter. Therefore, a cover that is transmissive at an emission wavelength of the light emitter can serve as a supporting and/or protective surface of the sensor module. Particularly for tapping movements, i.e. movements in an emission direction of the light source can be restricted by means of the transmissive cover. Transmissive in this context refers to an emission wavelength of the light emitter. For example, the transmissive cover is a glass or plastic cover that is transparent in the UV, visible and/or infrared domain.

In some further embodiments, a main extension plane of the transmissive cover is perpendicular or at an angle to the emission direction. A perpendicular arrangement may be beneficial from a space-saving point of view, wherein an overall dimension of the sensor module could be minimized for this arrangement. Moreover, the sensor module can comprise means to avoid back-reflections from a cover glass. These means can comprise an anti-reflective coating of the cover, which works most efficient at an angle of incidence of about 90 degrees. An angled arrangement of the cover, on the other hand, can aid to suppress back reflections without any additional coatings and therefore increase the sensor module's sensitivity to smooth surfaces of the object, e.g. a finger covered by a leather glove. An angled arrangement further can be chosen for non-trivial shapes of a housing of an electronic device the sensor module is to be employed in.

In some embodiments, the self-mixing interferometry sensor module further comprises an optical lens arranged distant from the light emitter in an emission direction of the light emitter. A lens can be employed for defining an emission area of the light sensor and therefore to shape a detection area of the sensor module. The lens can be arranged distant or directly above a top surface of the light emitter. For example, the lens is arranged between the light emitter and an optional transmissive cover of the sensor module.

Furthermore, an electronic device is provided, the electronic device comprising a self-mixing interferometry sensor module according to one of the aforementioned embodiments as well as a processing unit coupled to the sensor module. The processing unit is configured to receive the output signal from the sensor module, and extract the information of the determined movement of the object from the output signal. The processing unit is further configured to select a feature of the electronic device, and control the feature based on the information. The electronic device can be a handheld device such as a smartphone, a tablet computer, a remote of a television set, a wearable such as a smartwatch or fitness tracker, or any other electronic device that employs user input via gesture and/or touch, e.g. laptop computers, car-infotainments, household appliances and the like.

The processing unit can be a central processing unit, CPU, of the electronic device, or a system-on-a-chip, SOC, that is dedicated to process user inputs, for instance. The processing unit is coupled to the sensor module and receives the output signal from the latter. The output signal contains information about a detected movement, e.g. a direction, distance and/or speed of the movement as well as further optional data about an identified finger, for instance. The processing unit is configured to interpret the output signal as an input for a feature of the device, e.g. a volume control, a display control, channel selection etc. To this end, the processing unit converts the output signal into a control signal and provides this control signal to the respective addressed component of the electronic device, e.g. a sound controller.

In some embodiments, the processing unit is further configured to select the feature based on the extracted information. In contrast to embodiments, in which the sensor module serves to replace mechanical buttons of a single specific purpose, e.g. for volume control, the processing unit in these embodiments can add additional degrees of functionality. For example, depending on a property of a movement, e.g. a speed, an orientation or a direction, the processing unit can be configured to interpret the detected movement as an input for different features of the electronic device. For example, if the processing unit extracts and recognizes a certain aspect of the detected movement, the component or feature to be controlled can be chosen based on this aspect.

In some embodiments, the processing unit is further configured to compare the information to a first and a second movement pattern, select and control the feature if the information matches the first movement pattern, and select and control a further feature of the electronic device if the information matches the second movement pattern. For example, the processing unit extracts from the output signals information about an orientation of the movement with respect to the principle axes, for instance. The processing unit further compares this orientation to the first movement pattern, e.g. indicating a movement along a first axis, and to a second movement pattern, e.g. indicating a movement along a second axis, which is different from the first axis, respectively. Therein, the processing unit can be configured to interpret a movement along a first axis, e.g. an x-axis, as an input query for a first feature, e.g. a volume of sound, and a movement along a second axis, e.g. a y-axis, as an input query for a second feature, e.g. selection of a next/previous item in a playlist of stored media items. Furthermore, the processing unit can compare the detected orientation of the movement to further axes, e.g. an orientation along a third axis such as a z-axis indicating a tapping, and associate a movement along the third axis as an input query for a further feature, e.g. a play/pause query for media being output via a speaker.

In some embodiments, the processing unit is further configured to extract from the output signal a determined direction of movement, and control the feature depending on the direction. Movements along a specific axis can differ in terms of a sense or direction of the movement along said axis, i.e. forward or backward along said axis. Thus, the processing unit can be configured to extract from the output signal information about a direction of the detected movement along a specific axis and interpret a movement in a forward direction as an input query of a first feature in a first sense, and a movement in a backward direction as an input query of a first feature in a second sense. For example, a forward direction triggers an increase of sound volume or selects a next item in a playlist, while a forward direction triggers a decrease of sound volume or selects a previous item in a playlist.

In some embodiments, the processing unit is further configured to extract from the output signal a determined orientation of movement, and control the feature depending on the orientation. The processing unit can be configured to extract from the output signal information about an orientation of the detected movement with respect to the principle axes, for example, and interpret a movement along a first orientation as an input query of a first feature, and a movement along a second orientation as an input query of a second feature. For example, a movement along the first orientation triggers a change of sound volume, while a movement along the second orientation triggers a change of other sound properties such as a bass.

In some embodiments, the processing unit is further configured to extract from the output signal a determined speed of movement, and control the feature depending on the speed. Like a sense of direction, the speed of the movement can be extracted and used in an analogous manner. For example, a slow movement in a given direction is interpreted as an input query to fast forward a media currently being played at a first speed, while a slow movement in a given direction is interpreted as an input query to fast forward the media at a second higher speed. Alternatively, an increase or decrease rate of sound volume could be adjusted in dependence of the detected speed of the movement.

In some embodiments, the processing unit is further configured to extract the information of the determined movement of a user's finger from the output signal, extract information of an identified finger of the user from the output signal, and select and control the feature depending on the identified finger and the determined movement. As aforementioned, the processing unit can be configured to output a control signal for different features of the electronic device depending on which finger has been detected by the SMI sensor module. For example, the processing unit is configured to interpret a movement with an index finger along a given orientation as query for adjusting a first feature, e.g. a volume, and a movement with a middle finger along the same orientation as query for adjusting a second feature, e.g. adjusting a bass of sound output via a speaker.

In some embodiments, the electronic device further comprises a speaker operable to generate sound, wherein the feature corresponds to a volume of the sound generated by the speaker, and wherein the processing unit is configured to increase or decrease the volume depending on a direction of the detected movement. In such embodiments, the conventional mechanical buttons for volume adjustment are replaced by an SMI sensor module, which can provide additional functionalities and advantages described above. Moreover, some electronic devices, like in-ear speakers typically lack functionality of adjusting parameters of the sound being output or merely feature a single means of adjusting, e.g. via a tapping, which is not suitable for adjustments of features such as volume or bass of music.

In some embodiments, the electronic device further memory to store a playlist of media items, e.g. songs, wherein the feature corresponds to selecting a next or previous media item in the playlist, and wherein the processing unit is configured to select the next or the previous media item depending on a direction of the detected movement. For example, a sensor module can be configured to detect movements along the three principle axes, i.e. a swiping on a device surface or a tapping, and the processing unit translates the detected movement into the adjustment of specific features. A first axis could be used for volume control, a second axis for a fast forwarding or rewinding, while the third axis, e.g. representing a tapping motion, could be used for discrete inputs, such as play/pause, picking up a phone call or for activating a voice assistant.

Further embodiments of the electronic device become apparent to the skilled reader from the aforementioned embodiments of the self-mixing interferometry sensor module, and vice-versa.

Furthermore, a method of detecting movements is provided, wherein the method comprises emitting, by means of a light emitter, coherent electromagnetic radiation out of a sensor module, and inducing, within the light emitter, self-mixing interference, SMI, caused by reflections of the emitted electromagnetic radiation from an object outside the sensor module. The method further comprises detecting a change in an electrical property of the light emitter caused by the SMI, determining from the detected change a movement of the object outside the sensor module, and generating an output signal that comprises information of the determined movement.

Further embodiments of the method become apparent to the skilled reader from the aforementioned embodiments of the self-mixing interferometry sensor module and of the electronic device, and vice-versa.

### BRIEF DESCRIPTION OF THE DRAWINGS

The following description of figures may further illustrate and explain aspects of the self-mixing interferometry sensor module and the method of detecting movements. Components and parts of the self-mixing interferometry sensor that are functionally identical or have an identical effect are denoted by identical reference symbols. Identical or effectively identical components and parts might be described only with respect to the figures where they occur first.

Their description is not necessarily repeated in successive figures.

### DETAILED DESCRIPTION

In the figures:

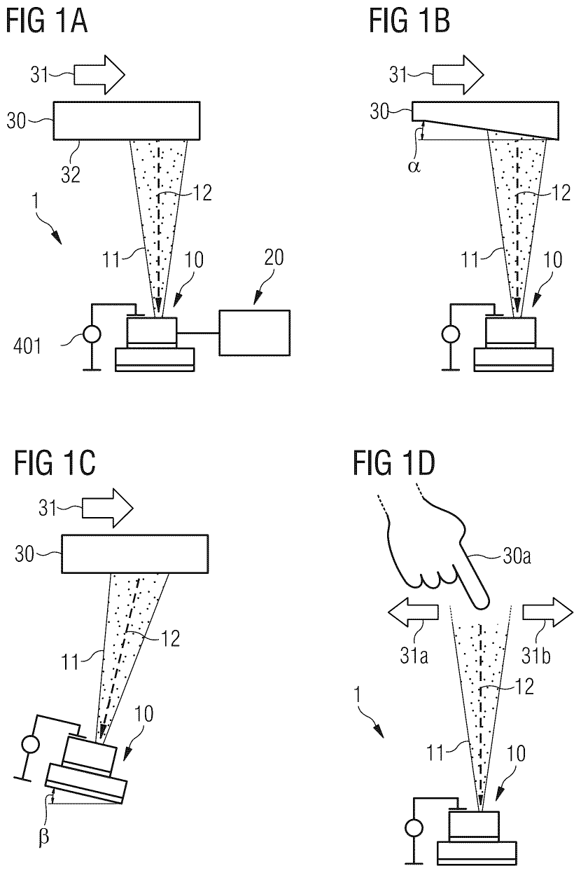

FIGS. 1 to 3 show various exemplary embodiments of a self-mixing interferometry sensor module according to the improved concept;

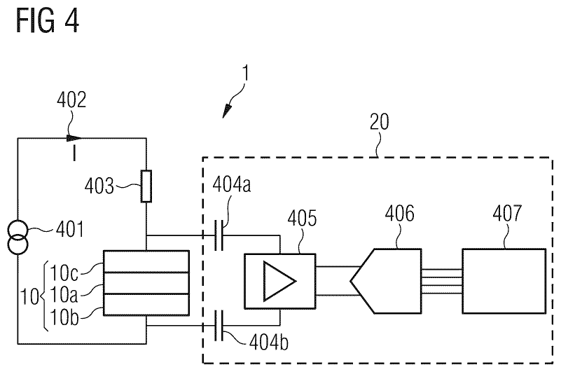

FIG. 4 shows a detailed schematic of a self-mixing interferometry sensor module;

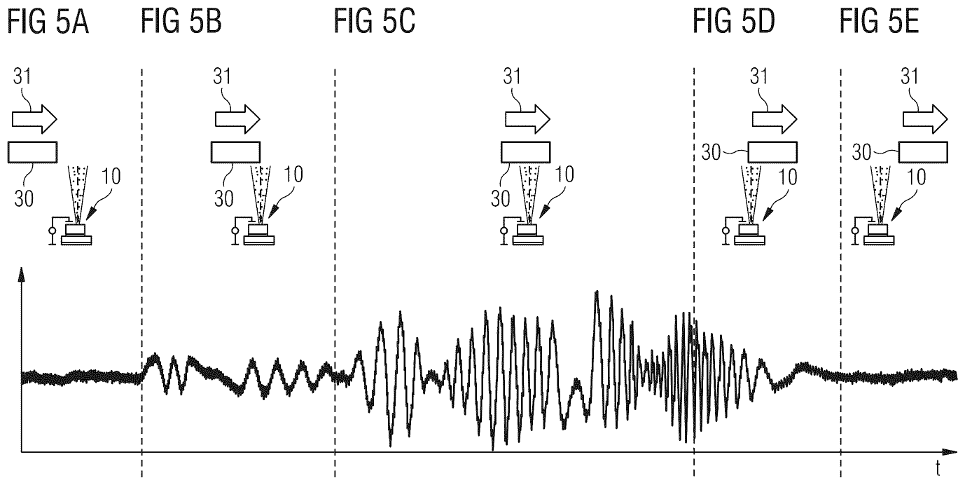

FIGS. 5 to 9 show exemplary electronic signals caused by self-mixing interference in a sensor module; and

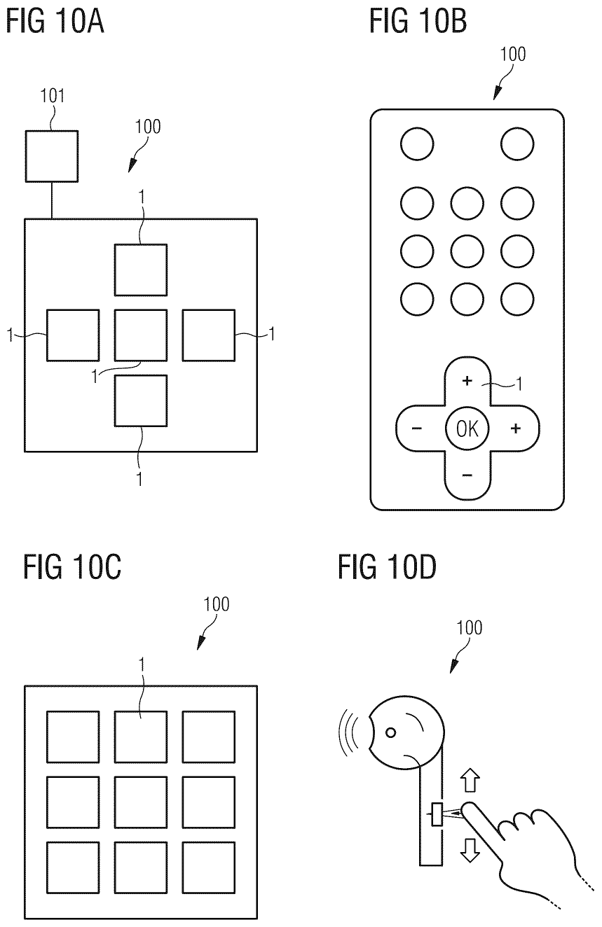

FIG. 10 shows various embodiments of an electronic device comprising a self-mixing interferometry sensor module.

FIG. 1 in panels 1a to 1d shows a first exemplary embodiment of a self-mixing interferometry, SMI, sensor module 1 according to the improved concept. First referring to FIG. 1a, the SMI sensor module 1 comprises a light emitter 10 that is configured to emit coherent electromagnetic radiation 11 out of the sensor module. The light emitter 10 can be a laser light source such as a vertical-cavity surface-emitting laser, VCSEL, which emits light into a vertical direction with respect to a main extension plane of the VCSEL, i.e. a bottom or top surface. The light emitter 10 can be configured to emit light in the infrared, IR, visible or ultraviolet, UV, domain of the electromagnetic spectrum. For example, the light emitter 10 is based on GaAs/AlGaAs materials and emits light in the range of 750-980 nm, in particular around 850 nm. Other longer wavelength of e.g. 1.3 μm, 1.55 μm or beyond 2 μm can be obtained using a VCSEL with alternative materials, such as indium phosphide, for instance. The light emitter is coupled to a voltage or current source 401, which is part of a diode driver circuit, for instance.

The light emitted electromagnetic radiation 11 can be a collimated or a diverging beam, the latter being indicated in the Figure. A diverging beam profile can be advantageous for achieving a larger emission area and thus being susceptible to reflections from a target in a larger area. In other words, the effective field-of-view of the sensor module is defined by the divergence of the emitted light 11.

The SMI sensor module 1 is further configured to back-inject reflected light 12 into a cavity of the light emitter 10, e.g. a laser cavity. Therein, the reflected light 12, in the figure indicated as the dashed arrow, is reflected from an object 30 moving across the field-of-view of the sensor module 1 with a movement vector 31. The object 30 can be a body part of a user, such as a finger or the face, or a component of an electronic device the sensor module 1 is employed in, e.g. a stylus pen or a slider. In particular, the object 30 is at least partially opaque with respect to an emission wavelength of the light emitter 10, such that at least a fraction of the emitted light 11 is reflected of a surface of the object 30.

As the emitted light 11 is coherent, the reflected light 12 is superimposed with the light inside the laser cavity depending on the phase shift introduced by the round trip travel to and from the object 30. This in turn leads to changes in the properties of the light emitted from the light emitter 10 including the output frequency, the line width, the threshold gain and consequently the output power. Thus, the occurring self-mixing interference results in a modulation of the frequency (and optionally of the amplitude) of the laser oscillating field inside the cavity. A movement of the object 30 along the movement vector 31, e.g. a hand gesture, causes a distance between the reflecting surface 32 of the object 30 to fluctuate, thus effectively forming a vibrating target. Therein even smallest topographic features on the reflecting surface 32 suffice for the formation of SMI inside the light emitter 10. In other words, the self-mixing interference is even caused in the depicted case, in which the reflection surface 32 of the object 30 is along a movement vector 31 that is substantially perpendicular to an emission direction of the light emitter 10.

The SMI sensor module 1 further comprises an electronic control unit 20 that is coupled to the light emitter 10 such that an electrical property of the light emitter 10 can be detected by means of the electronic control unit 20. For example, the electronic control unit 20 comprises means to monitor and detect a junction voltage of the light emitter 10, e.g. a VCSEL junction voltage. Alongside the optical power of the light emitter 10, the junction voltage is likewise affected by self-mixing and also shows a modulation behavior upon movement of the object 30. It is noted, however, that while the output power varies proportionally with the change in target location, the junction voltage exhibits an inverse relationship. In other words, an increase in laser power coincides with a decrease in laser junction voltage. Alternatively, the electronic control unit 20 can comprise means to monitor and detect changes in a laser current of the light emitter 10, showing a similar modulation due to a moving object 30.

The electronic control unit 20 further comprises means to analyze the electrical property and determine from a detected change in the electrical property the movement of the object 30 and to generate an output signal that comprises information of the movement vector 31. A schematic of an electronic control unit 20 is shown and described in FIG. 4.

Panels 1b and 1c illustrate that the SMI sensor module 1 can also determine movements of the object 30 in case of the emitted light 11 not impinging onto the reflecting surface 32 in a perpendicular but in an angled manner. For instance, the reflecting surface 32 can have an angle α with respect to a main plane of extension of the light emitter 10, or the light emitter 10 itself is arranged at an angle β with respect to the reflecting surface 32. Due to a finite but non-zero roughness of the reflecting surface 32, also these arrangements fulfill the requirement that at least a fraction of the emitted light 11 is reflected back into a cavity of the light emitter 10. Therein, it is noted that self-mixing interferometry can be realized for displacements even as small as about 2% of the emission wavelength of the light emitter 10.

Panel 1d illustrates the sensor module 1, wherein the emitted light 11 is reflected off a finger 30a. Therein, the friction fringes of the finger 30a possess a surface roughness with large enough magnitude that an efficient operation of the sensor module 1 due to a high amount of SMI is enabled. Therein, the sensor module 1 can determine a movement of the finger 30a along different movement vectors 31a, 31b, e.g. in opposite directions. In panels 1b to 1d as well as in the following figures, the electronic control unit 20 is omitted for illustrative purposes.

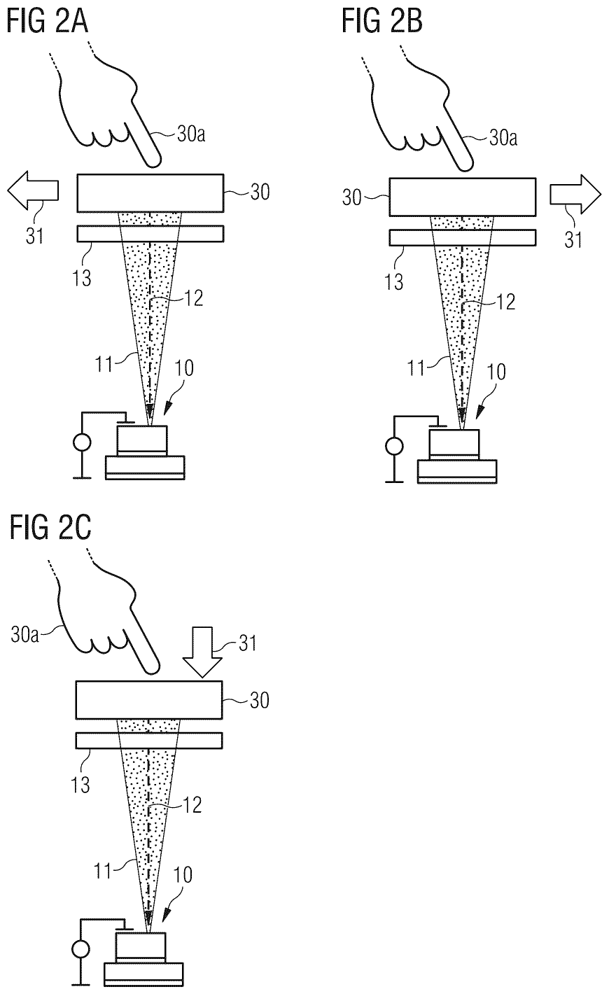

FIG. 2 in panels 2a to 2c shows a second exemplary embodiment of a self-mixing interferometry, SMI, sensor module 1. In this embodiment, the sensor module 1 further comprises a transmissive cover 13 that is arranged distant from the light emitter 10 in an emission direction of the latter. In other words, the transmissive cover 13 is arranged distant from a main extension plane of the emitter 10. The term transmissive in this context refers to an emission wavelength of the light emitter 10. For example, no emitted light 11 is reflected from a surface of the transmissive cover 13 such that the reflected light 12 is exclusively light that is reflected from the object 30.

The object 30 can be comprised by the sensor module 1 or it can be a component of an electronic device the sensor module 1 is employed in. For example, the object is an opaque plastic element or a stylus pen that is configured to slide along the plane defined by a surface of the transmissive cover 13, as illustrated in FIGS. 2a and 2b. The object 30 during the movement can be in contact with the transmissive slider or be arranged distant from the latter. Particularly in the latter case, also a tapping movement of the object towards the light emitter 10 as indicated in FIG. 2c is enabled and likewise induces SMI inside the cavity of the light emitter 10.

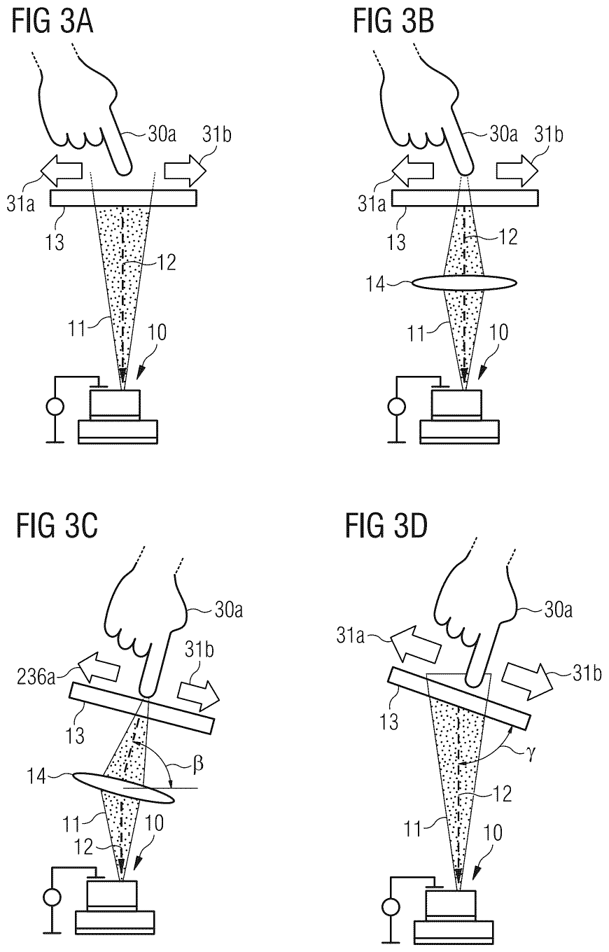

FIG. 3 in panels 3a to 3d shows a third exemplary embodiment of a self-mixing interferometry, SMI, sensor module 1. Similar to the second embodiment, the sensor module 1 comprises a transmissive cover 13 that acts as a touch surface. Like before, the emitted light 11 is only or substantially only reflected at the reflecting surface 32 of the object 30, in this case a finger 30a. Thus, the electronic control unit 20 of the sensor module 1 is configured to detect a movement of the finger 30a along a movement vector 31a, 31b on a surface of the transmissive cover 13, e.g. a cover glass or a transparent dielectric. The movement vector 31a, 31b can be aligned with a first axis as indicated, or with a second axis perpendicular to an emission direction of the light emitter 10 and the first axis, i.e. the second axis is arranged perpendicular to the drawing plane. The electronic control unit 20 can be configured to determine a deviation of the movement vector 31 from said first and second axes. Additionally, the electronic control unit 20 can be configured to determine a tapping movement that is oriented along a third axis that is parallel to the emission direction of the light emitter, i.e. perpendicular to the top surface of the transmissive cover 13.

The embodiments of FIGS. 3b and 3c comprise an additional lens element 14 arranged in between the light emitter 10 and the transmissive cover 13. The lens element 14 can be configured to perform beam shaping for defining a spot size of the emitted light 11, and hence a field-of-view of the sensor module 1, at a top surface of the transmissive cover 13. As illustrated in FIG. 3c, the transmissive cover 13 can be arranged at an angle β with respect to a main extension plane of the light emitter 10. Accordingly, the lens element 14 can be arranged at a corresponding angle in order to direct the emitted light 11 towards the intended portion of the transmissive cover 13. FIG. 3d shows an arrangement analogous to that of FIG. 1c, in which the cover 13 is arranged at an angle γ with respect to an emission direction of the light source 10. Such angled arrangements can be advantageous for applications, in which a surface of the housing of the electronic device is not parallel to a main extension plane of the sensor module 1.

FIG. 4 shows a detailed schematic of a self-mixing interferometry sensor module 1, and in particular of the electronic control unit 20. The sensor module 1 comprises a VCSEL as light emitter 10 that comprises an active region 10a stacked between bottom and top mirrors 10b, 10c. The light propagates in the vertical direction, which is orthogonal to the active region plane. The current 402 is injected from the mirrors via a driver circuit comprising a supply source 401 and a resistor 403. For measuring the electrical property of the light emitter 10, in this case a modulation of the junction voltage, the electronic control unit 20 comprises AC coupling and DC blocking capacitors 404a, 404b that couple the light source to an amplifier 405 for amplifying the signal.

Optionally, the amplifier 405 can also act as a filter, e.g. a bandpass filter, such that an output of the amplifier 405 substantially only comprises frequency contributions from the SMI induced by the back-injected light 12 into the light emitter 10. The output of the amplifier 405 can be coupled to an analog-to-digital converter, ADC, 406 before providing the digitalized signal to a processor 407 for generating the output signal. To this end, the processor 407 analyzes the digitalized signal, e.g. by means of extracting frequencies and/or amplitudes of the modulation caused by the SMI and generates the output signal that carries information about said modulation and thus about the detected movement.

The electronic control unit 20 can together with the light emitter 10 form an integrated circuit device on a common chip substrate, for instance. Therefore, the self-mixing interferometry sensor module 1 can be a CMOS integrated circuit device

FIG. 5 illustrates the working principle of a self-mixing interferometry sensor module 1 according to the improved concept. To this end, FIG. 5 shows the resulting signal of the electrical property, e.g. the junction voltage, of the light emitter 10 when moving an object 30 along a movement vector 31 across the field-of-view of the sensor module 1. In panel (a), the moving object 30 is moving towards the field-of-view of the light emitter 10, defined by its beam divergence of the emitted light 11, but has not yet entered the field. In other words, no emitted light 11 impinges onto the object 30. Thus, the signal of the junction voltage is dominated by noise and shows no further contributions due to SMI.

In panel (b), the object 30 enters the field-of-view of the sensor module 1 such that a portion of the light is reflected from the object 30, i.e. from a reflecting surface 32, back towards the light emitter 10, indicated as the dashed line, where it is reinjected into the cavity and causes a self-mixing interference as described above. This leads to an amplitude and/or frequency modulation of the junction voltage resulting in the sinusoidal behavior. As the object 30 moves further into the field-of-view of the sensor module, as illustrated in panel (c), a larger fraction of the emitted light 11 impinges on the object 30 and is reflected back to the light emitter 10, leading to even stronger SMI and thus to a stronger modulation of the junction voltage signal monitored by the electronic control unit.

Eventually, the object 30 is moved out of the field-of-view such that first the modulation signal decreases due to weaker back-reflection (panel (d)) before the object in panel (e) is again outside the emission area of the light emitter similar to panel (a).

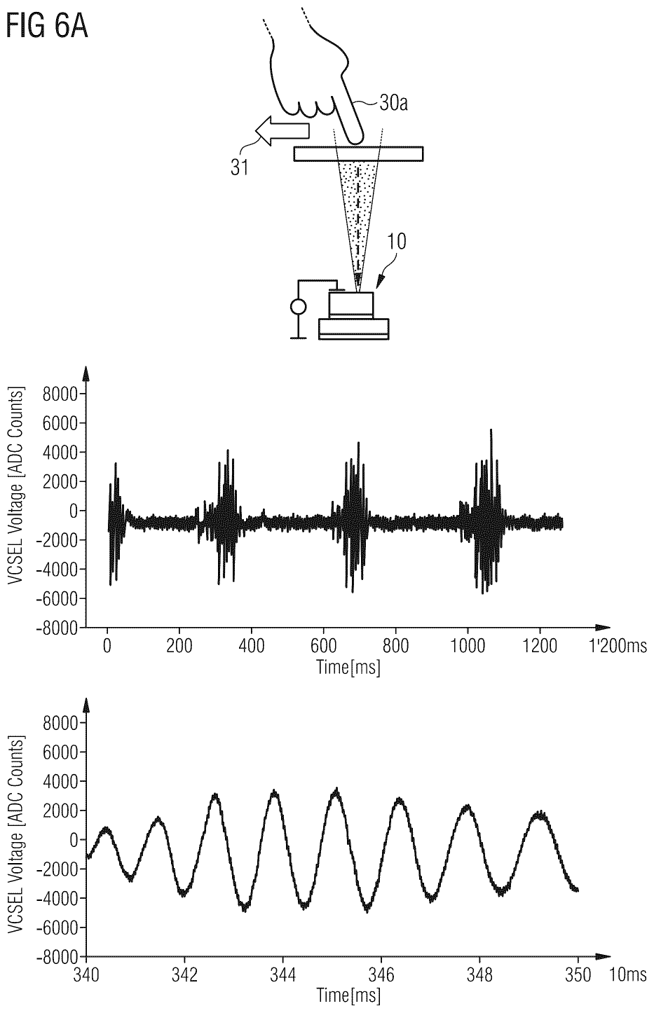

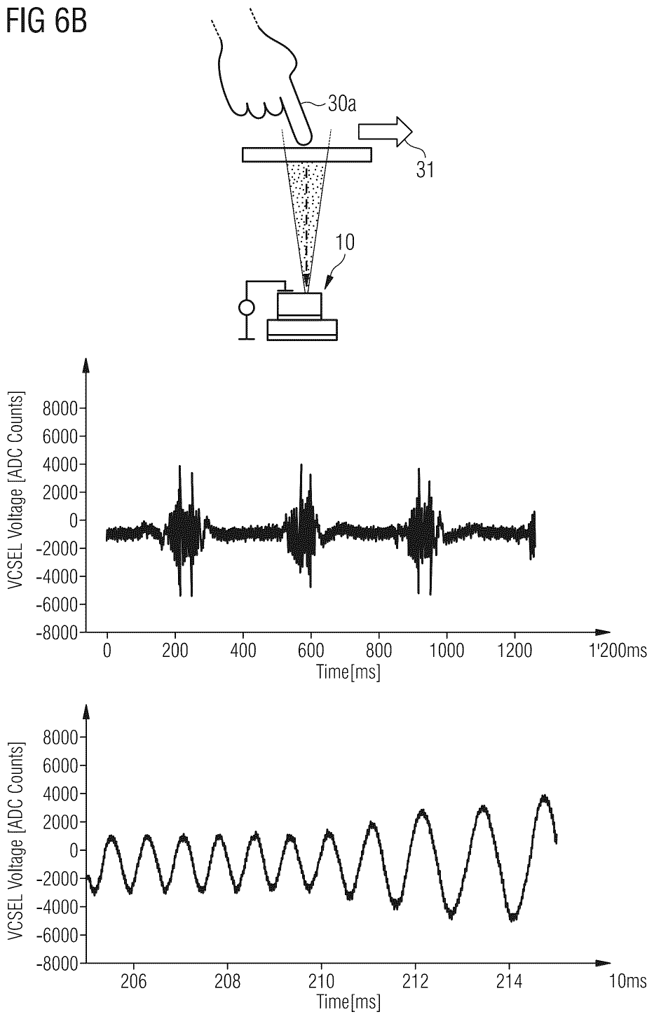

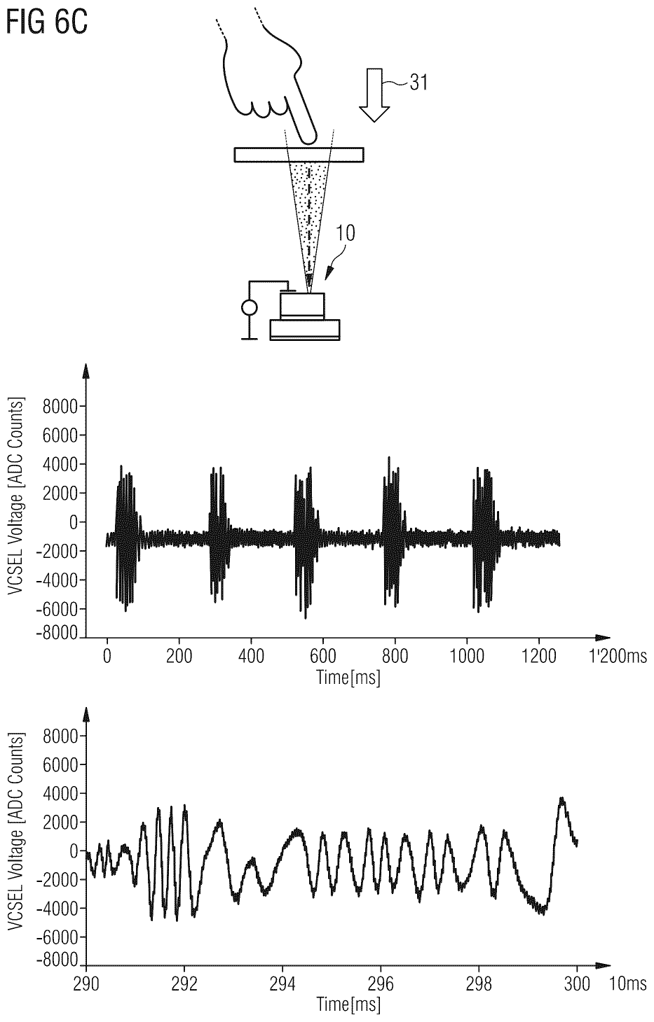

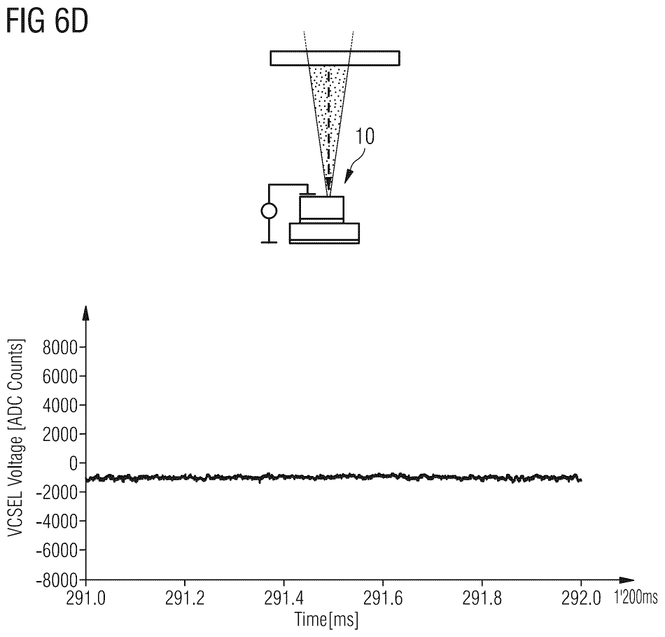

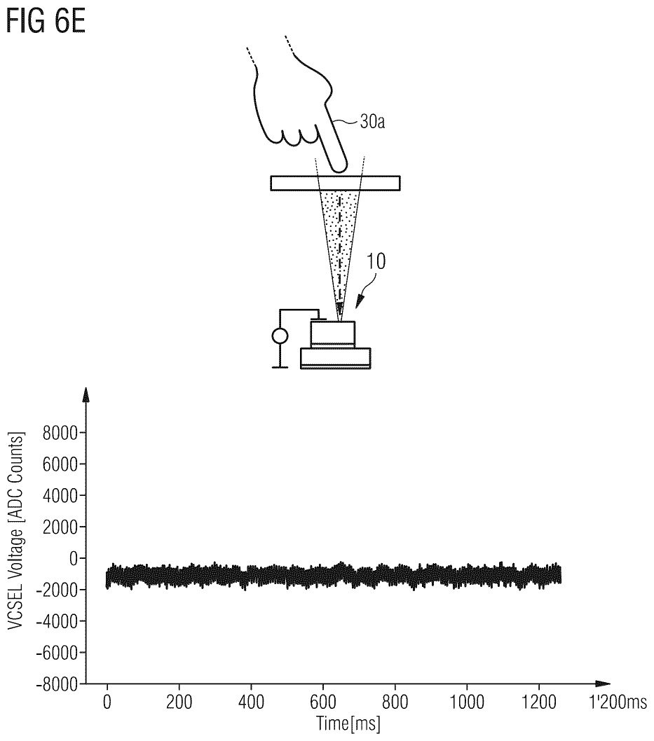

FIG. 6 compares the resulting junction voltage signal of the third embodiment of the SMI sensor module 1 due to different movements of the object 30, in this case a finger 30a. FIG. 6a shows the resulting signal for a finger 30a that moves in a first direction along an axis, while FIG. 6b shows the resulting signal for a finger 30a that moves in second direction along said axis, wherein the second direction is opposite the first direction. For example, the first movement is to the left and the second movement is to the right. The center graph in the respective figures shows the resulting signal for repeated movements, while the respective bottom graph is a zoom into a feature of the resulting signal in terms of the x-axis constituting the time axis. As can be seen, the resultant signal of the finger moving to the left significantly differs from the case that the finger moves to the right. Hence, the electronic control unit 20 can easily distinguish what direction along a certain axis an object 30 is moved into. Thus, an accordingly generated output signal can contain information about the axis, the direction and optionally the speed of the movement via pattern recognition and/or slope analysis in the resulting modulation signal. This signal could in turn be used to increase or decrease a sound volume of an electronic device the sensor module 1 is employed in.

FIG. 6c shows the resulting signal of a repeated tapping movement, i.e. a movement of the finger 30a along the emission axis of the light emitter 10. Again, the center graph shows the resulting signal of the junction voltage for a repeated tapping movement while the bottom graph shows a zoom into a feature of the center graph. It is noted that the tapping motion likewise causes a modulated signal that is easily distinguishable from those of FIGS. 6a and 6b. It is thus emphasized that a sensor module 1 employing a single light emitter 10 is sufficient to detect a direction and an orientation of the movement 31.

FIGS. 6d and 6e show the resulting signal in the absence of an object within the emission area of the light source and in case a finger 30a is resting on a surface of the transmissive cover 13, respectively. In the first case, substantially no fraction of the emitted light 11 is reflected back into the light emitter 10 such that the signal of the junction voltage over time is constant with little noise contribution, e.g. due to electronic noise. With a resting finger 30a, the signal likewise maintains a constant level without any apparent modulation caused by SMI since no movement is taking place, however, the noise contribution is larger as a fraction of the emitted light 11 is reflected and back-injected into the cavity of the light emitter 10.

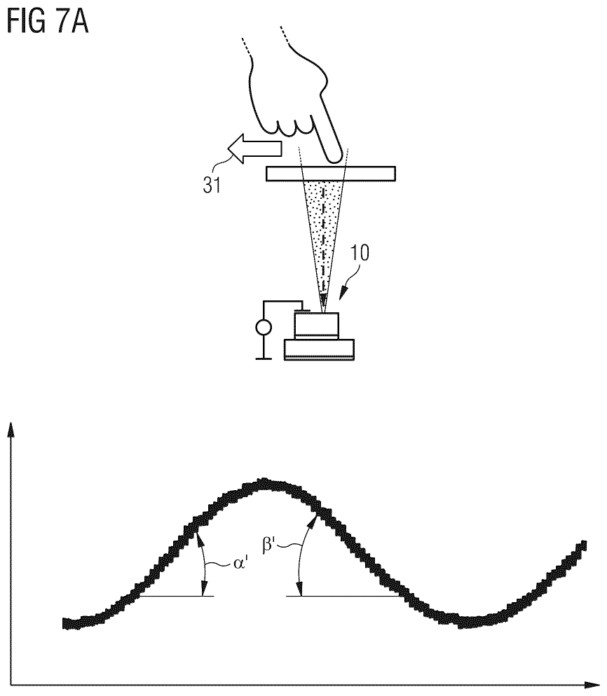

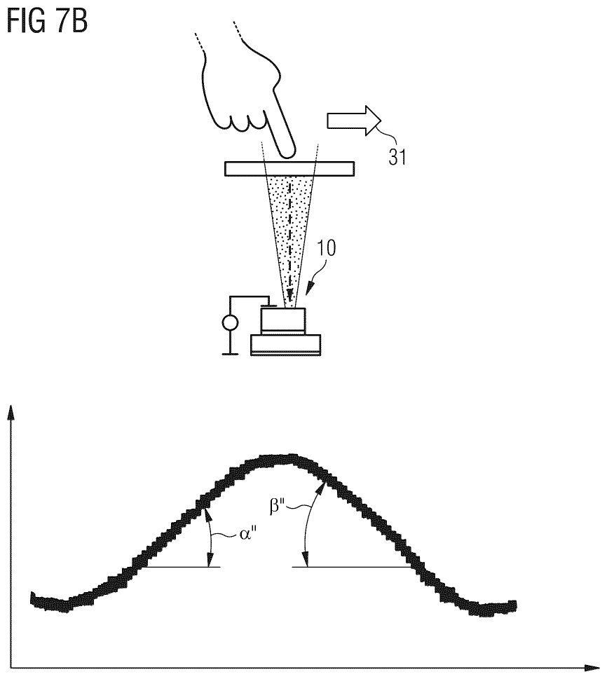

FIGS. 7a and 7b compare an angle of the rising slope α′, α″ and that of the falling slope β′, β″ in the resulting modulated junction voltage signal in the use cases of FIGS. 6a and 6b, respectively. With a movement to the left of FIG. 6a, a zoom into a single modulation fringe of the junction voltage signal reveals in FIG. 7a an angle α′ of the rising slope that is smaller than an angle β′ of the falling slope. In contrast, with a movement to the right of FIG. 6a, a zoom into a single modulation fringe of the junction voltage signal reveals in FIG. 7b an angle α″ of the rising slope that is larger than an angle β″ of the falling slope. Hence, an accordingly generated output signal can contain information about the direction of the movement via a comparison of the angles of the rising and falling slopes of the resulting modulation signal.

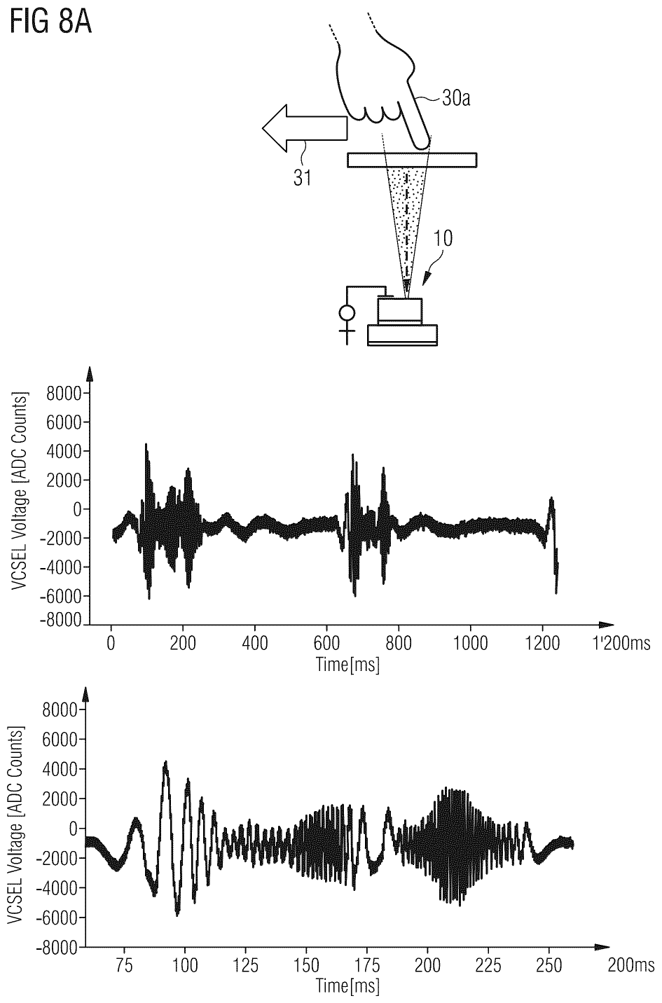

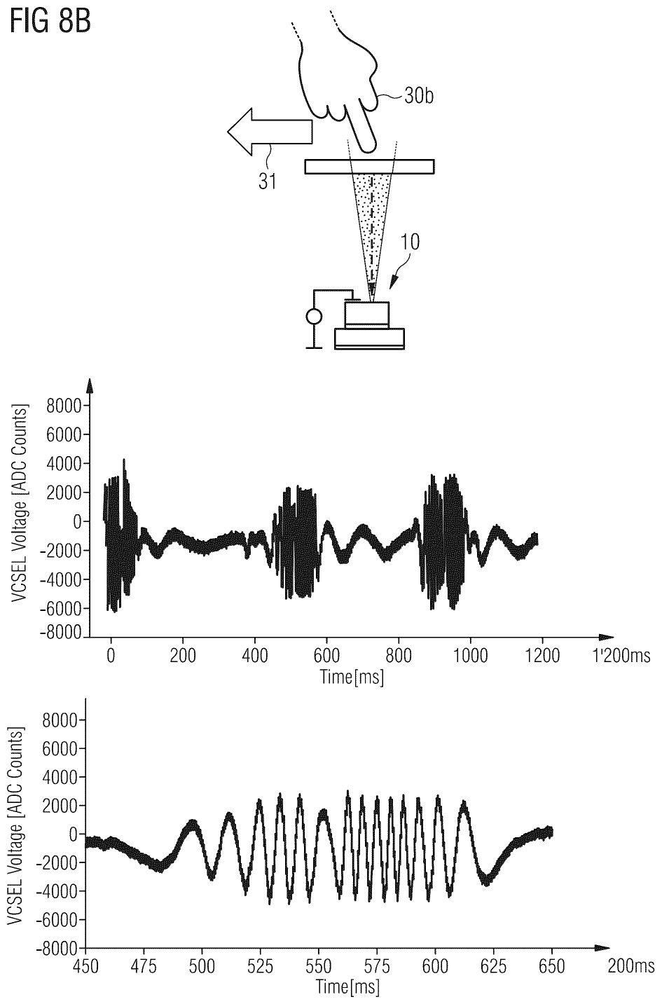

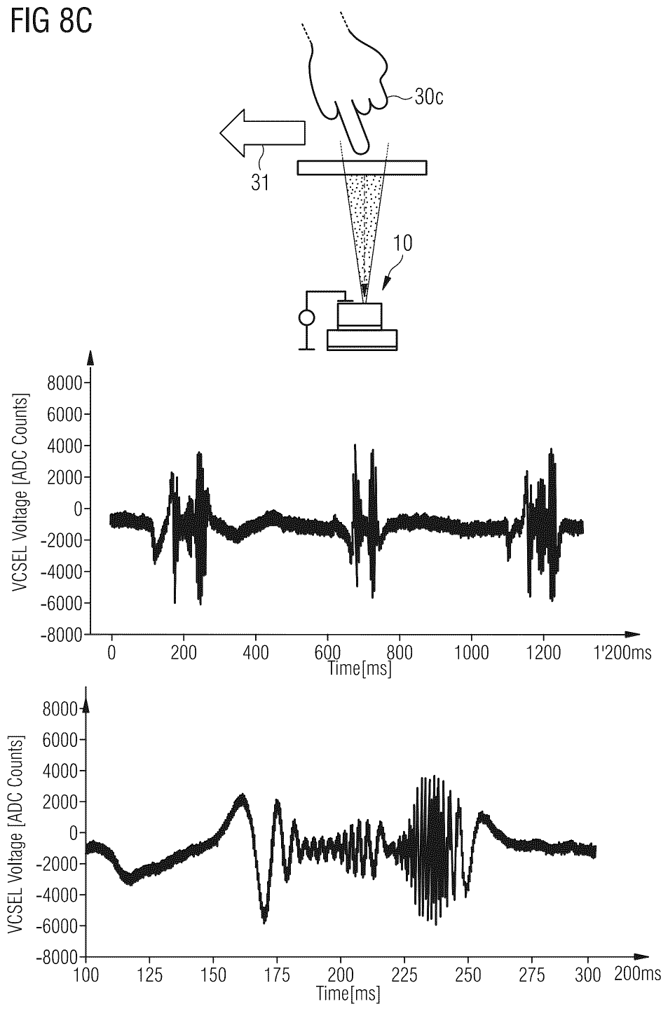

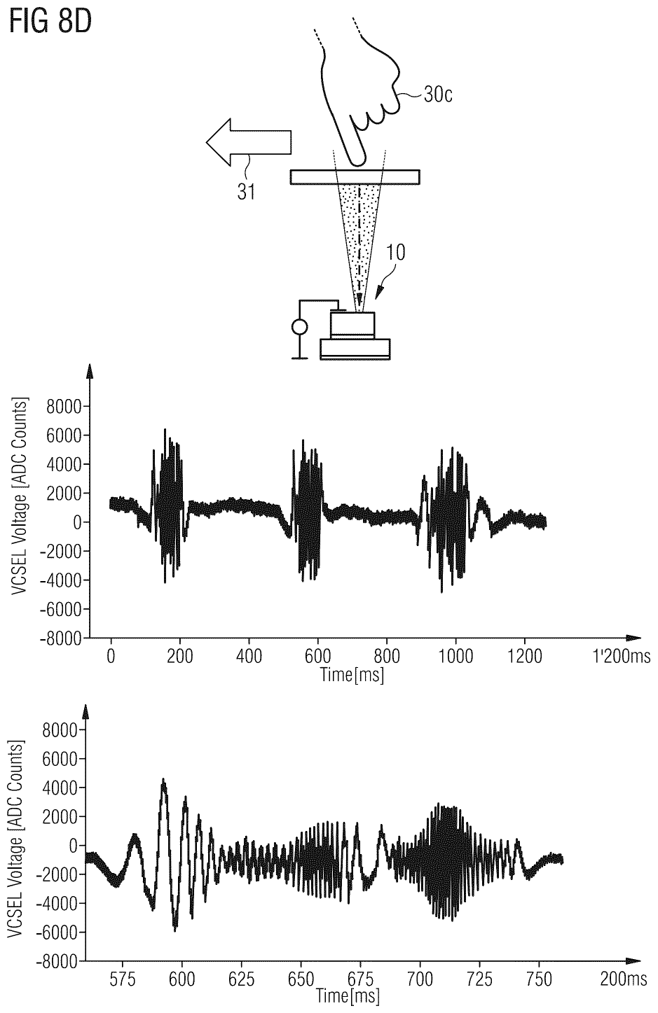

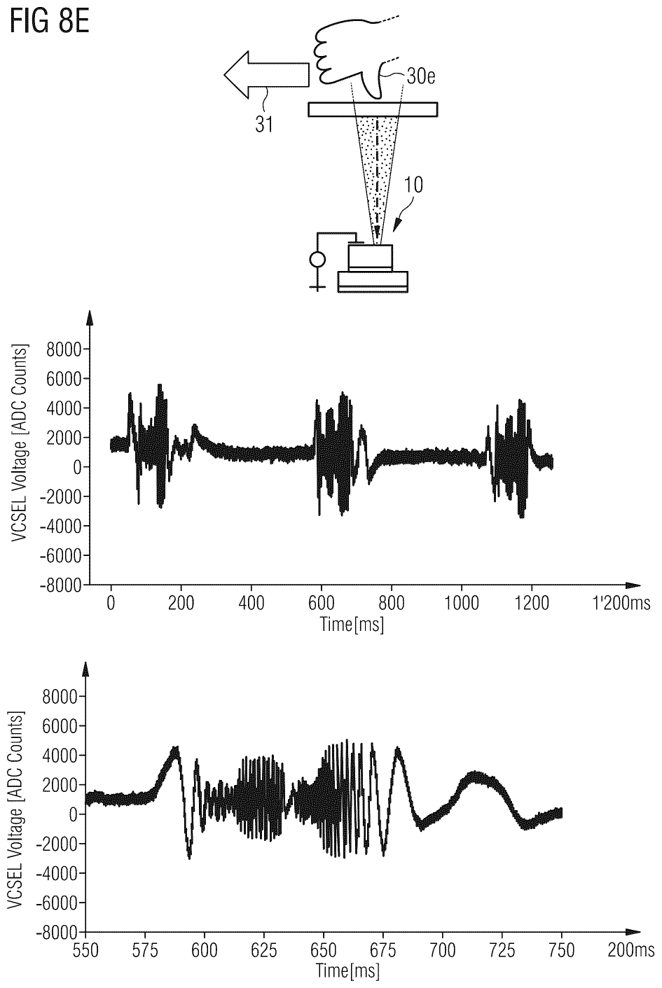

FIGS. 8a to 8e compare the resulting junction voltage signal of the third embodiment of the SMI sensor module 1 due to a movement along the same movement vector 31a but performed with different fingers 30a-e of a user. As can be seen from the respective resulting signals of the FIGS. 8a to 8e, the individual finger used for the movement due to the unique fingerprints can be clearly discerned since the resulting signals substantially differ in terms of the frequency and/or amplitude modulation. It is noted that a movement with a different finger is already discernable independently from the fingerprint due to the human anatomy itself. A movement with a middle finger can mean a different posture of the elbow compared to a movement with an index finger, and thus mean a slightly different path of movement, for example.

For example, an electronic device the sensor module is employed in could be configured to collect a set of training data, in which the user is prompted to slide different fingers across the sensor module such that for sensing purposes, the finger 30a-30e can be identified and an information about the finger 30a-30e used for the movement can be included in the output signal. For example, this signal could be used to, for a movement with an index finger along a given orientation, increase or decrease a sound volume, or for a movement with a middle finger along the same orientation, skip forward or backward an item in a playlist of an electronic device the sensor module 1 is employed in.

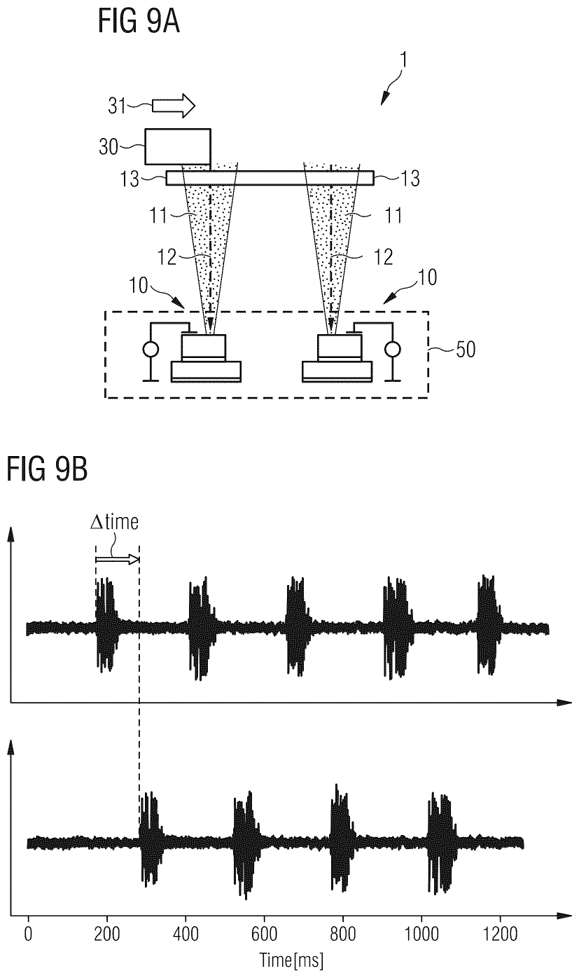

FIG. 9 shows an exemplary embodiment featuring a plurality of light emitters 10 arranged on a common substrate or within a common module housing 50. Using multiple light emitters that each can undergo self-mixing interference, a movement across a larger distance can be monitored if the field-of-views are arranged adjacent to each other along an axis of the movement vector 31. FIG. 9a shows an example employing two light emitters 10. The working principle of each of these light emitters is analogous to the embodiments of the sensor module 1 according to the embodiments discussed above. Utilizing two modules, however, also provides a convenient way of monitoring a speed of the movement via monitoring a time difference of a feature of the resulting modulation signals of the first light emitter 10 (upper graph of FIG. 9b) and the second light emitter 10 (lower graph of FIG. 9b).

FIG. 10 shows exemplary embodiments of electronic devices 100 comprising an SMI sensor module 1 according to the improved concept. FIG. 10a shows an electronic device 100 employing a plurality of sensor modules 1 arranged adjacent to each other, wherein each of the sensor modules 1 can be configured to control a distinctive feature of the electronic device upon a detected movement in its respective sensing area. For example, each of the sensor modules 1 is configured to initiate one of the following: increase or decrease a sound volume, switching to a next or previous item in a playlist or channel in a channel list, or for confirming a selection. To this end, the output signals generated by the sensor modules 1 is provided to a processing unit 101 that is coupled to the sensor modules 1 and is configured to extract information about the detected movements from the output signals received from one or more of the sensor modules 1, and to cause an adjustment of the targeted property of the electronic device 100 in manner corresponding to the detected movement.

Such a sensor arrangement can for example be employed in a TV remote control as depicted in FIG. 10b, a smart phone, a laptop computer, a wearable or any other device that is based on user inputs. Alternatively, as described a single sensor module 1 could likewise distinguish movements of an object 30 into different directions, along different axes and/or at different speeds, such that particularly for smaller scale devices, e.g. in-ear headphones or wearable devices, the employment of a single sensor module 1 according to the improved concept suffices to enable detection of different movements. This is in contrast to conventional mechanical buttons that merely allow a single or two use cases, e.g. via a single and a double push. However, these conventional solutions do not allow for any stepless adjustment of properties such as a volume using a single button module.

The embodiment of the electronic device 100 of FIG. 10c illustrates a system employing a plurality of sensor modules arranged in a grid-like pattern. On such a device, e.g. a touch pad of a laptop computer or a touch screen, a movement along various axes and with different speeds can be monitored over larger distances compared to use cases that employ a single sensor module 1, making the detection of movements even more accurate across large surfaces.

The embodiment of the electronic device 100 of FIG. 10d illustrates a system with a single sensor module 1 employed in an in-ear speaker. A single sensor module 1 having a single light emitter 10 can be used to determine a movement along a first orientation, e.g. for adjusting a sound level, along a second orientation, e.g. for selecting a next or previous item in a playlist, or a tapping movement for switching between a play/pause state and/or to activate further features such as a voice assistant, for instance. A determined speed of the movement can be used to set a degree of adjustment of the respective property, for instance. For more accurate readings, multiple sensor modules 1, e.g. according to the arrangement of FIG. 10a, could be employed depending on space and energy requirements.

This patent application claims the priority of the U.S. patent application No. 63/310,233 the disclosure content of which is hereby incorporated by reference.

The embodiments of the self-mixing interferometry sensor module and the method of determining a movement of an object disclosed herein have been discussed for the purpose of familiarizing the reader with novel aspects of the idea. Although preferred embodiments have been shown and described, changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

### REFERENCES

1 self-mixing interferometry module
10 light emitter
10a active region
10b, 10c end mirror
11 emitted light
12 reflected light
13 transmissive cover
14 lens
20 electronic control unit
30 object
30a-e finger
31, 31a, 32b movement vector
50 common housing
100 electronic device
101 processing unit
401 source
402 current
403 resistor
404a, 404b capacitor
405 amplifier
406 analog-to-digital converter
407 processor
α, β, γ angles

1. A self-mixing interferometry sensor module, comprising
a single light emitter configured to
emit coherent electromagnetic radiation out of the sensor module; and
undergo self-mixing interference, SMI, caused by reflections of the emitted electromagnetic radiation from an object outside the sensor module; and
an electronic control unit coupled to the light emitter and configured to
detect a change in an electrical property of the light emitter caused by the SMI;
determine from the detected change a movement of the object outside the sensor module; and
generate an output signal that comprises information of the determined movement, wherein
a direction and an orientation of the movement along all three motion principle axes of the object is determined.

2. The self-mixing interferometry sensor module according to claim 1, wherein the light emitter is a vertical cavity surface emitting laser, VCSEL, diode.

3. The self-mixing interferometry sensor module according to claim 1, wherein the electronic control unit is configured to detect a change in a junction voltage of the light emitter and determine from the change in junction voltage the movement of the object.

4. The self-mixing interferometry sensor module according to claim 1, wherein the electronic control unit is further configured to
determine from the detected change a speed of the movement; and
generate the output signal that comprises information of the determined speed.

5. The self-mixing interferometry sensor module according to claim 1, wherein the electronic control unit is further configured to
determine from the detected change a direction of the movement along a movement axis; and
generate the output signal that comprises information of the determined direction.

6. The self-mixing interferometry sensor module according to claim 1, wherein the electronic control unit is further configured to
determine from the detected change an orientation of the movement with respect to a first axis and a second axis; and
generate the output signal that comprises information of the determined orientation.

7. The self-mixing interferometry sensor module according to claim 1, wherein the electronic control unit is configured to determine from the detected change a movement of a finger of a user outside the sensor module.

8. The self-mixing interferometry sensor module according to claim 7, wherein the electronic control unit is further configured to
identify from the detected change a finger of the user; and
generate the output signal that comprises information of the identified finger.

9. The self-mixing interferometry sensor module according to claim 1, further comprising a transmissive cover that is arranged distant from the light emitter in an emission direction of the light emitter, wherein the transmissive cover serves as a surface for the movement of the object.

10. The self-mixing interferometry sensor module according to claim 9, wherein a main extension plane of the transmissive cover is perpendicular or at an angle to the emission direction.

11. The self-mixing interferometry sensor module according to claim 1, further comprising an optical lens arranged distant from the light emitter in an emission direction of the light emitter.

12. An electronic device comprising a self-mixing interferometry sensor module according to claim 1 and a processing unit coupled to the sensor module, wherein the processing unit is configured to
receive the output signal from the sensor module;
extract the information of the determined movement of the object from the output signal;
select a feature of the electronic device; and
control the feature based on the information.

13. The electronic device according to claim 12, wherein the processing unit is further configured to select the feature based on the extracted information.

14. The electronic device according to claim 12, wherein the processing unit is further configured to
compare the information to a first and a second movement pattern;
select and control the feature if the information matches the first movement pattern; and
select and control a further feature of the electronic device if the information matches the second movement pattern.

15. The electronic device according to claim 12, wherein the processing unit is further configured to
extract from the output signal a determined direction of movement; and
control the feature depending on the direction.

16. The electronic device according to claim 12, wherein the processing unit is further configured to
extract from the output signal a determined speed of movement; and
control the feature depending on the speed.

17. The electronic device according to claim 12, wherein the processing unit is further configured to
extract the information of the determined movement of a user's finger from the output signal;
extract information of an identified finger of the user from the output signal; and
select and control the feature depending on the identified finger and the determined movement.

18. The electronic device according to claim 12, further comprising a speaker operable to generate sound, wherein
the feature corresponds to a volume of the sound generated by the speaker; and
the processing unit is configured to increase or decrease the volume depending on a direction of the detected movement.

19. The electronic device according to claim 12, further including memory to store a playlist of media items, wherein
the feature corresponds to selecting a next or previous media item in the playlist; and
the processing unit is configured to select the next or the previous media item in the memory depending on a direction of the detected movement.

20. A method of detecting movements, comprising:
emitting, by means of a single light emitter, coherent electromagnetic radiation out of a sensor module;
inducing, within the light emitter, self-mixing interference, SMI, caused by reflections of the emitted electromagnetic radiation from an object outside the sensor module;
detecting a change in an electrical property of the light emitter caused by the SMI;
determining from the detected change a movement of the object outside the sensor module; and
generating an output signal that comprises information of the determined movement, wherein
a direction and an orientation of the movement along all three motion principle axes of the object is determined.
